(19) United States
(12) Patent Application Publication
(10) Pub. No.: US 2007/0104888 A1
(43) Pub. Date: May 10, 2007

(54) Method for the organised growth of nanostructures

(75) Inventors: Frederic Mazen, Grenoble (FR); Thierry Baron, Saint Egreve (FR); Sebastien Decossas, Grenoble (FR); Abdelkader Souifi, Clonas Sur Vareze (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: Comminssariat A L"energie Atomique, Paris (FR)

(21) Appl. No.: 10/584,053

(22) PCT Filed: Dec. 21, 2004
(86) PCT No.: PCT/FR04/50743

§ 371 Date: Jun. 22, 2006

(30) Foreign Application Priority Data
Dec. 23, 2003 (FR) 0651186

(51) Int. Cl. C23C 16/00; C23C 16/24; H05H 1/00

(52) U.S. Cl. 427/533; 427/255.18; 427/255.393; 977/891

(57) ABSTRACT

The invention concerns a process for the formation of nanostructures including:
the formation of nucleation sites (4) by the irradiation of a substrate using a beam of silicon or germanium ions,
the growth of nanostructures (8) on the nucleation sites thus formed.

### TECHNICAL AREA AND PRIOR ART

This present invention concerns a process for the creation of organised 3D nanostructures, particularly in a semiconductor material.

The nanostructures take the form of a network. They are created on a substrate which can be a dielectric layer, in SiO₂, or Al₂O₃, or Si₃N₄, or HfO₂ for example, or in another metal oxide.

These nanostructures are intended for the creation of electronic optical or opto-electronic devices (memories, single-electron transistors, etc.). In particular, it concerns coulomb blockade devices for the implementation of quantic islands. These nanostructures are also intended for the creation of probes for bio-chips, when a piece of DNA can be attached to a nanostructure.

The constant improvement in the performance of microelectronic circuits requires a rate of integration of their elementary component (the MOSFET) that is always more advanced. To this ends up to the present, the microelectronic industry has been able to reduce the dimensions of the MOSFET by optimising the technological processes without encountering major physical limitations in its operation.

In the short or medium term however, the “SIA Roadmap” has specified a grid size of the order of 35 nm, below which quantic effects will disrupt the correct operation of the transistors.

It is therefore necessary to develop alternative solutions to the CMOS technology.

One of the most promising paths is to employ the charge retention and/or coulomb blockade properties of nanostructures. There is therefore a current effort to integrate these nanostructures, mainly created in silicon, into devices.

There are several processes for producing these nanostructures. Chemical vapour deposition (CVD) in the gas phase can be used to deposit nanostructures on a dielectric on an industrial scale.

It has already been possible to integrate these nanostructures into devices such as memories or transistors.

The deposition of silicon nanostructures (ns-Si) onto dielectric by CVD, including the formation of a new layer of silicon, by CVD, from precursors such as silane or disilane, is of the Volmer-Webber type, in which firstly three-dimensional islets are formed which grow up to coalescence, until they form a continuous layer. By stopping the growth during the first stages of the deposition, it is thus possible to create islets of nanometric dimensions.

The main limitation of this technique is that the nanostructures are located randomly on the substrate, as shown in reference [1] mentioned at the end of this present description. This is due to the spontaneous nature of the process of nucleation of the silicon on the dielectric.

In fact, these nanostructures form preferentially on sites or defects whose location on the surface of the substrate cannot be controlled at present. This considerably limits the quality and the performance of the devices based on such structures.

To be able to organise the distribution of these nanostructures, it is therefore necessary to create preferential nucleation sites that are distributed regularly on the surface of the substrate. To this end, it has been proposed that nanostructures should be placed on a substrate of SiO₂ that has a regular deformation field on its surface. The nanostructures deposited on this type of substrate organise themselves in lines, as described in reference [2] mentioned at the end of this present description.

However, the resulting organisation is not satisfactory and the spacing between the nanostructures is very difficult to control. Moreover, this method imposes the use of very fine dielectrics which do not guarantee the electrical isolation between the nanostructures and the substrate.

This then leaves the problem of finding a process that will allow control over the location and the growth of the nanostructures.

### PRESENTATION OF THE INVENTION

This present invention allows the creation of a regular network of nucleation sites in order to control the location and the growth of nanostructures. The latter are deposited, for example, by chemical vapour deposition (CVD) onto a substrate, which can advantageously be in a dielectric material.

In other words, this present invention allows the organisation of nanostructures on a surface.

In a first stage, the surface of the substrate is functionalised locally by the deposition of a nucleation site by means of a focussed ion beam (FIB), such as a beam of silicon ions or germanium ions, for example.

In a second stage, the nanostructures grow selectively, by chemical vapour deposition (CVD) for example, on the nucleation sites previously formed by the FIB process.

According to the invention, nucleation centres are therefore deposited regularly by means of a focussed ion beam (FIB). Three-dimensional nanostructures then grow selectively on the nucleation centres thus formed.

In particular, the invention allows the creation, on an insulator, of an organised deposition of semiconductor nanostructures, of Silicon or Germanium or in semiconductor material of the IV or III-V type for example. It is also possible to prepare metal nanostructures.

The location of these nanostructures is controlled since the FIB process allows very localised irradiation, and so the formation of very localised growth sites, and also allows control of the spacing between the nanostructures.

Finally, the density of these nanostructures is also controlled, since it is equal to the density of the sites created by FIB.

The size of the nanostructures is therefore controlled correctly, and the dispersion in size is reduced in relation to a random deposition of nanostructures.

The element used for the irradiation can be the same as, or can have properties close to, the element of which the nanostructures are composed. The electrical or optical properties of the nanostructures are then not degraded by the presence of impurities.

### BRIEF DESCRIPTION OF THE FIGURES

FIGS. 1 and 2 represent stages of a process according to the invention.

### DETAILED PRESENTATION OF METHODS OF IMPLEMENTATION OF THE INVENTION

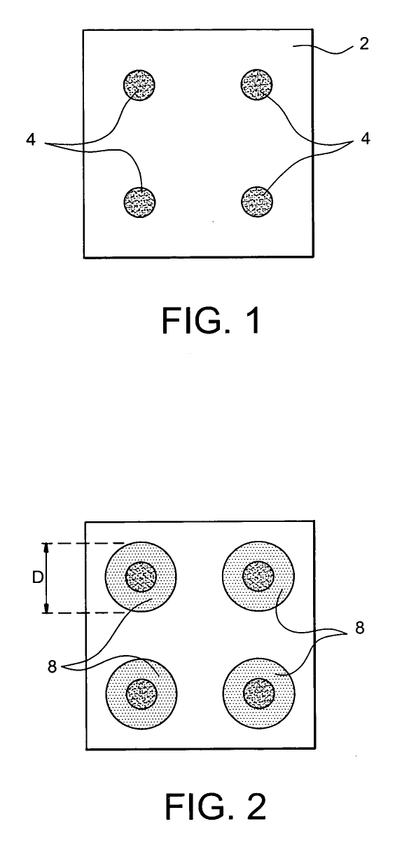

A process according to the invention will now be described, with reference to FIGS. 1 and 2.

In a first stage, a surface (2) is exposed to an ion beam for the local deposition upon it of a material which will act as preferred nucleation sites (4), on which the nanostructures can then grow.

A Focused Ion Beam is used for this purpose. An FIB workstation, employed to this end, is used to focus the ion beams very precisely onto the surface of the substrate (2) with a very high current density.

Such a workstation is described, for example, in document 4 mentioned at the end of this present description.

The exposure of predetermined zones of the surface to the focussed ion beam (FIB) generates a local modification of the properties of the substrate (2).

A reactive site (4) created by irradiation by the ion beam can, for example, be an amas (a few atoms) of the element used for irradiation of the surface, or can be an introduction of this element into the substrate, or again can be defects created by the ionic bombardment (or implantation).

Nucleation sites (4) are therefore firstly created at the chosen positions by irradiation of the surface with a beam of localised ions (a focussed ion beam).

The element used for irradiation of the surface preferably has properties close to the element making up the nanostructures that one wishes to create. In order to make nanostructures of silicon or germanium, it is possible to irradiate with silicon for example. It is also possible to use a beam of germanium.

In a second stage, nanostructures (8 in FIG. 2) in three dimensions are formed on the sites (4) formed previously.

To this end, use is preferably made of a precursor which generates a selective deposition on the site in relation to the substrate.

For example, if the dielectric is SiO₂, and if the preliminary irradiation is effected with silicon, it is then possible to deposit silicon or germanium nanostructures by the use of Dichlorosilane or Germane respectively, which are precursors that can be used to generate a deposition on a selective silicon site in relation to an SiO₂ substrate. This is particularly the case if the irradiation is such that aggregates of silicon, or zones very rich in silicon, form at the surface of the substrate.

The nanostructures therefore grow selectively on the irradiated zones (4).

The desired material is deposited selectively on the nucleation sites (4) by chemical vapour deposition (CVD) for example.

According to the invention, a deposition of the nucleation site (a few atoms of a selected material) is therefore first performed by FIB, though the FIB technique is known to be ineffective in principle for the creation of a 3D nanostructure, or in volume.

Next comes the selective growth of the nanostructures (8) on the growth germs deposited by FIB. The growth of each nanostructure is thus very localised and its size controlled to a maximum diameter D, measured in a plane parallel to plane 2, of the order of a few nanometres, and between 1 nm and 10 nm or 15 nm or 20 nm for example. The height can be about 100 nm for example, and the approximate shape of these structures between a hemisphere and a sphere. In microelectronic applications, the height will be less than 20 nm and advantageously of the order of 10 nm.

The nanostructures thus located regularly are formed at a density that can be between 10⁸/cm² and 10¹³/cm².

The size dispersion achieved is less than 20%, and when the average of all the sizes is calculated, there is a difference between crystals of less than 20%.

In addition, the intervention of an electrochemical process is not indispensable to the creation of such a selective growth, as in certain known processes.

After the growth of nanostructures, different thermal treatments can be applied in order to improve their electrical or optical properties, particularly to repair the defects engendered by irradiation of the substrate (2).

The invention concerns all materials that present deposition selectivity in relation to the substrate (2). Irradiation by FIB then brings site nucleation to the deposited material.

For example, it is possible to use the invention advantageously in order to deposit, selectively and locally, onto a substrate which can have the nature of an insulator (such as SiO₂, Al₂O₃, SiNₓ, etc.), materials of the column IV type (such as silicon carbide (SiC), Diamond C, etc.), or type III-V materials (gallium arsenide, gallium nitride, GaP, etc.), or metals, etc.

### REFERENCES MENTIONED IN THIS PRESENT DESCRIPTION

[1]: T. Baron, F. Martin, P. Mur, C. Wyon, M. Dupuy, Journal of Crystal Growth 290 (2000), 1004-1008.
[(2)]: T. Baron, F. Mazen, C Busseret, A. Souifi, P. Mur, M. N. Semeria, F. Fournel, P. Gentile, N. Magnea, H. Moriceau, B. Aspar, Microelectronic Engineering 61-62 (2002), 511.
[3]: P. Schmuki, L E. Erickson, G. Champion, Journal of the Electrochemical Society, vol. 148, no 3, (2001), C177.
[(4)]: R. Gerlach, M. Utlaut, Proceedings of the SPIE, The International Society for Optical Engineering, vol 4510 (2001), 96.

1. A process for the formation of nanostructures that includes:
forming nucleation sites, in volume, by the irradiation of a substrate by means of a beam of ions, by localised deposition of atoms suitable for the formation of such sites, and
growing by chemical vapor deposition nanostructures on the nucleation sites thus formed.

2. (canceled)

3. The process according to claim 1, wherein the substrate is in a dielectric material.

4. The process according to claim 3, wherein the substrate is a silicon dioxide (SiO₂) or an aluminium oxide (Al₂O₃) or a silicon nitride (SiNₓ).

5. (canceled)

6. The process according to claim 1, said semiconductor material being silicon or germanium.

7. The process according to claim 6, said nanostructures formed being created respectively by means of dichlorosilane or germane, as a gaseous precursor.

8. The process according to claim 1, said nanostructure being in a semiconductor material of the column IV type.

9. The process according to claim 8, said nanostructure being in silicon carbide (SiC) or in Diamond C.

10. The process according to claim 1, said nanostructure being in a III-V type semiconductor material.

11. The process according to claim 1, said nanostructure being in gallium arsenide (GaAs), or in gallium nitride (GaN), or in gallium phosphide (GaP).

12. (canceled)

13. The process according to claim 1, said nanostructures being in 3 dimensions.

14. The process according to claim 1, said nanostructures being of maximum diameter (D) between 1 nm and 15 nm.

15. The process according to claim 1, nanostructures being formed at a density between 10⁸/cm² and 10¹³/cm².

16. The process according to claim 1, wherein said beam of ions is a beam of silicon or germanium ions.

17. A process for the formation of 3 dimensional nanostructures in a semiconductor material that includes:
forming nucleation sites, in volume, by the irradiation of a substrate, by localized deposition of atoms suitable for the formation of such sites, and
growing by chemical vapor deposition of nanostructures on the nucleation sites thus formed.

18. The process according to claim 17, wherein said substrate is in a dielectric material.

19. The process according to claim 17, wherein said semiconductor material is silicon or germanium.

20. The process according to claim 17, wherein said nanostructures are created respectively by means of dichlorosilane or germane, as a gaseous precursor.

21. The process according to claim 17, wherein said nanostructures are in a semiconductor material of the column IV type or are in a III-V type semiconductor material.

22. The process according to claim 17, wherein said nanostructures are in gallium arsenide (GaAs), or in gallium nitride (GaN), or in gallium phosphide (GaP).

23. The process according to claim 17, wherein said nanostructures are of maximum diameter (D) between 1 nm and 15 nm.

24. The process according to claim 17, wherein said nanostructures are formed at a density between 10⁸/cm² and 10¹³/cm².

25. The process according to claim 17, wherein said substrate is irradiated by a beam of silicon or germanium ions.
